(19) United States
(12) Patent Application Publication
(10) Pub. No.: US 2026/0015173 A1
(43) Pub. Date: Jan. 15, 2026

(54) MAPPING SYSTEM

(71) Applicant: TDK Corporation, Tokyo (JP)

(72) Inventors: Tatsuhiro Kotsugai, Tokyo (JP); Tomoshi Abe, Tokyo (JP); Kodai Sato, Tokyo (JP)

(73) Assignee: TDK Corporation, Tokyo (JP)

(21) Appl. No.: 19/265,497

(22) Filed: Jul. 10, 2025

(30) Foreign Application Priority Data
Jul. 11, 2024 (JP) 2024-111671

(51) Int. Cl. B65G 1/137

(52) U.S. Cl. CPC B65G 1/1371; B65G 2201/0297

(57) ABSTRACT

The present disclosure relates to a mapping system capable of accurately detecting an accommodated state of the object accommodated in the container even when the containers accommodating different objects are being transported within a semiconductor factory. A mapping system includes a substrate information acquisition unit acquiring a substrate information regarding a substrate accommodated in a predetermined container that is being transported or is in a state ready to be transported within a factory; a mapping threshold determining unit determining a mapping threshold used for mapping the predetermined container based on the substrate information; and a mapping unit for mapping the predetermined container using the mapping threshold

### BACKGROUND OF THE INVENTION

The present disclosure relates to a mapping system for detecting an accommodated state of an object in a container.

### Description of Related Art

A device such as a lord port apparatus which passes and receives a plate-form object such as a substrate is provided with a mapping apparatus which detects the accommodated state of the substrate accommodated in the container. The mapping apparatus detects the number and the position of the substrate accommodated in the container, and also detects whether the substrate has properly accommodated in the container (see Patent Document 1). Examples of the substrate detected by the apparatus includes a silicon substrate (including silicon wafer) and the silicon substrate which has been treated, and a thin plate-form material such as a glass substrate.

On the other hand, as the substrate, which is transported in a semiconductor factory has become larger and thinner, containers and the substrates accommodated in the containers have also become more diversified. For example, a container accommodating a silicon wafer having a size of 200 mm (8 inch) and a thickness of 0.625 mm, a container accommodating a silicon wafer having a size of 300 mm (12 inch) and a thickness of 0.775 mm may be transported simultaneously in a factory, and these two types of containers may be transported to the predetermined load port apparatus one after another. Also, a substrate having a plan shape of a rectangular shape, and a substrate which is thinner than the above-mentioned silicon wafer may be transported.

In the mapping apparatus used in such semiconductor treatment factory, it may be difficult to distinguish between a proper detection result and a detection result of an improper state when two substrates are accommodated in one shelf of the container. For example, in the case that the object is a wide and thin substrate, the center part which is not supported by the shelf may warp, and even if one substrate is properly accommodated in one shelf, this may give a detection signal similar to an improper accommodated state where two substrates each having small area are accommodated in one shelf.

### PRIOR ART DOCUMENT

### Patent Document

Patent Document 1: JP Patent Application No. 2011-35384

### BRIEF SUMMARY OF THE INVENTION

### Object to be Solved by the Invention

The present disclosure relates to a mapping system capable of accurately detecting an accommodated state of the object accommodated in the container even when the containers accommodating different objects are being transported within a semiconductor factory.

### Means for Solving the Problems

In order to achieve the above object, a mapping system according to the present disclosure includes: a substrate information acquisition unit acquiring a substrate information regarding a substrate accommodated in a predetermined container that is being transported or is in a state ready to be transported within a factory; a mapping threshold determining unit determining a mapping threshold used for mapping the predetermined container based on the substrate information; and a mapping unit for mapping the predetermined container using the mapping threshold.

The mapping system according to the present disclosure acquires substrate information which is the information regarding the substrate accommodated in a container transported in the factory, and also determines a mapping threshold for mapping the predetermined container based on the substrate information. Thereby, the mapping unit can perform mapping using the mapping threshold which is optimized to the substrate accommodated in the predetermined container. Thus, the mapping system according to the present disclosure can accurately detect the accommodated state of the object accommodated in the container even when the containers accommodating the different objects are transported within the semiconductor factory.

Also, the substrate information acquisition unit may include: a specific reference sign acquisition unit acquiring a specific reference sign of the predetermined container that is being transported or is in a state ready to be transported within a factory, a substrate information storage unit correlating and storing the specific reference sign and the substrate information of the predetermined container according to the reference sign, and an information readout unit reading the substrate information of the predetermined container corresponding to the specific reference sign from the substrate information storage unit using the specific reference sign acquired by the specific reference sign acquisition unit.

Such substrate information acquisition unit can acquire the substrate information regarding the substrate accommodated in the predetermined container simply by acquiring the specific reference sign of the predetermined container from this container. Thus, the container itself only needs to hold a simple information; hence, the system can be simplified.

The substrate information may contain information regarding a thickness of the substrate accommodated in the predetermined container, and the substrate information may contain information regarding a material of the substrate accommodated in the predetermined container.

When the thicknesses of the substrates are different, the substrates accommodated in the container warp differently; hence, by including the information regarding the thickness of the substrate in the substrate information, such mapping system can accurately detect the accommodated state of the substrate accommodated in the container. The same applies to the material of the substrate.

### BRIEF DESCRIPTION OF THE SEVERAL VIEWS OF THE DRAWING

FIG. 1 is a conceptual diagram of a semiconductor factory employing a mapping system according to the first embodiment of the present disclosure.

FIG. 2 is a conceptual diagram of information transmission carried out in each unit included in the mapping system shown in FIG. 1.

FIG. 3 is a conceptual diagram showing one example of a substrate information of the mapping system.

FIG. 4 is a conceptual diagram of a mapping threshold table which is used by a mapping threshold determining unit during a process of determining a mapping threshold using the substrate information.

FIG. 5A is a conceptual diagram showing one example of a relationship between a value of a detection signal by a mapping unit and a mapping threshold.

FIG. 5B is a conceptual diagram showing one example of a relationship between a value of a detection signal by a mapping unit and a mapping threshold.

FIG. 5C is a conceptual diagram showing one example of a relationship between a value of a detection signal by a mapping unit and a mapping threshold.

FIG. 5D is a conceptual diagram showing one example of a relationship between a value of a detection signal by a mapping unit and a mapping threshold.

FIG. 6A is a conceptual diagram showing a different warping state due to different thicknesses of the substrates accommodated in the container.

FIG. 6B is a conceptual diagram showing a different warping state due to different thicknesses of the substrates accommodated in the container.

FIG. 7 is a conceptual diagram showing a mapping arm included in the mapping system shown in FIG. 1.

FIG. 8 is a conceptual diagram showing a first step of a mapping operation of a mapping unit included in the mapping system shown in FIG. 1.

FIG. 9 is a conceptual diagram showing a second step of the mapping operation of the mapping unit included in the mapping system shown in FIG. 1.

FIG. 10 is a conceptual diagram showing a third step of the mapping operation of the mapping unit included in the mapping system shown in FIG. 1.

FIG. 11 is a conceptual diagram showing information transmission carried out in each unit included in the mapping system according to the second embodiment.

FIG. 12 is a conceptual diagram showing information transmission carried out in each unit included in the mapping system according to the third embodiment.

### DETAILED DESCRIPTION OF THE INVENTION

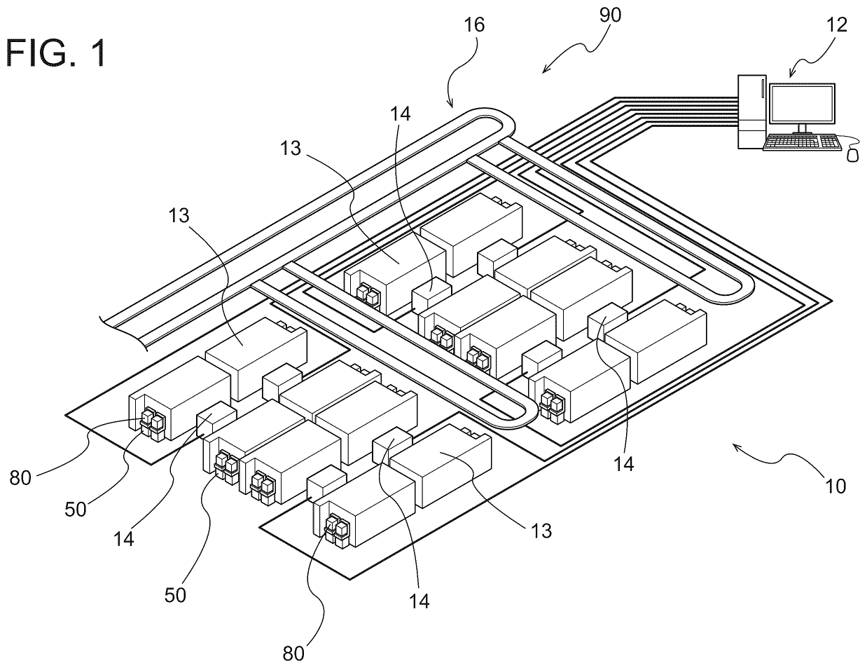

Below, the present disclosure is described based on the embodiments shown in the figures. FIG. 1 is a conceptual diagram of a semiconductor factory 90 employing a mapping system 10 according to the first embodiment of the present disclosure. As shown in FIG. 1, the semiconductor factory 90 has a plurality of processing devices 13. Each processing device 13 performs a predetermined treatment to various substrates including a silicon wafer. Examples of the processing device 13 include a film forming machine, a lithography system, an etching machine, a grinding machine, a molding machine, and other machines which are made by combining these. However, it is not particularly limited to these.

While being accommodated in the container 80, a substrate which may be an object to be treated in each machine, or a substrate which is used for the treatment is transported to each processing device 13. The semiconductor factory 90 includes a container transportation system 16 using OHT or so, and the container transportation system 16 transports the container 80 and the substrate accommodated in the container 80 to the processing device 13 arranged in the factory 90.

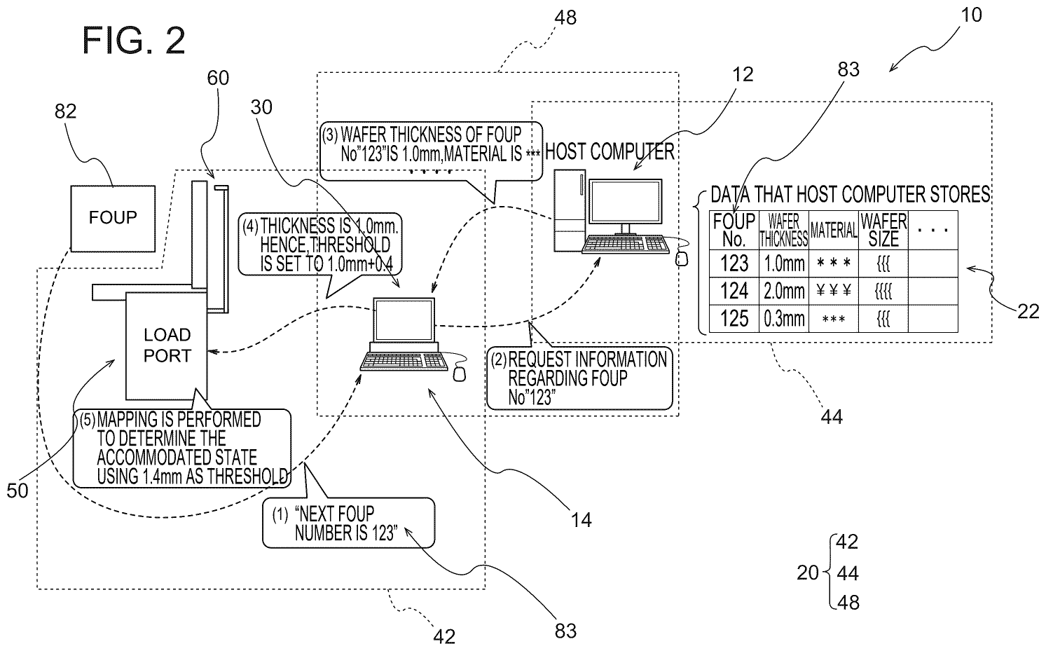

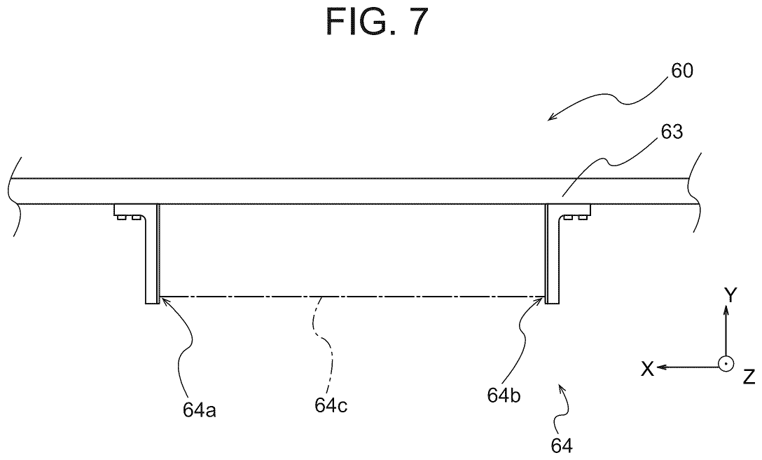

Each processing device 13 receives the container 80 from the container transporting system 16; and, a load port apparatus 50, which allows the container 80 to be taken out from the processing device 13, is installed to the processing device 13. Also, as mentioned later using FIG. 7 to FIG. 10, the load port apparatus 50 includes a mapping unit 60 which carries out mapping for the predetermined container 82 (see FIG. 2, and FIG. 7 to FIG. 10).

Here, the mapping carried out by the mapping unit 60 of the present disclosure means that the mapping unit 60 detects the accommodated state of the substrate in the predetermined container 82. More specifically, using the detection unit 64, the mapping unit 60 detects and determines, for each accommodating shelf provided in the predetermined container 82, whether the substrate is properly accommodated, improperly accommodated, or not accommodated. Note that, in the semiconductor factory 90, the mapping unit 60 is not limited to be included only in the load port apparatus 50, but it may also be provided to another device which detects the accommodated state of the substrates on accommodating shelves of the container 80 and the like.

As shown in FIG. 1, the factory 90 includes a processing device control unit 14 which controls each processing device 13. More specifically, the processing device control unit 14 controls each functioning part included in the corresponding processing device 13; and, it controls the movement of the substrate in the processing device 13, and the treatment to the substrate. In the example shown in FIG. 1, the processing device control unit 14 is provided to each processing device 13. Note that, the processing device control unit 14 does not necessarily have to be provided to the processing device 13 in a 1:1 relation, and one processing device control unit 14 may control a plurality of processing devices 13.

Also, the factory 90 includes a host computer 12. For example, the host computer 12 sends out an instruction to a container transportation system 16, the processing device control unit 14, etc.; and also, the host computer 12 receives information from the container transportation system 16, the processing device control unit 14, etc. Thereby, the host computer 12 controls the entire devices in factory 90. As show in FIG. 1, the host computer 12 is connected to the container transportation system 16, the processing device control unit 14 and the like, so that these can communicate using a cable capable of transferring signals, a wireless communication network, or so.

FIG. 2 shows a conceptual diagram showing information transmission (information transmissions (1) to (5)) carried out in each part configuring the mapping system 10 according to the first embodiment. As shown in FIG. 2, the mapping system 10 installed in the factory 90 incudes a mapping unit 60 included in the load port apparatus 50 and the like, the substrate information acquisition unit 20 acquiring the information of the substrate accommodated in the predetermined container 82 as the object to be mapped, and the mapping threshold determining unit 30 which determines the mapping threshold from the substrate information.

In the mapping system 10, as a device, the mapping threshold determining unit 30 is mainly configured of the processing device control unit 14. To this, the substrate information acquisition unit 20 is configured by the processing device control unit 14, the host computer 12, the load port apparatus 50, and so on working together. As these devices work together, the substrate information acquisition unit 20 acquires the substrate information 22, which is information regarding a substrate accommodated in a predetermined container 82 (see FIG. 2), among the containers 80 (see FIG. 1) that are being transported within the factory 90 or are in a state ready to be transported.

More specifically, the substrate information acquisition unit 20 includes a specific reference sign acquisition unit 42, a substrate information storage unit 44, and an information readout unit 48 as shown in FIG. 2. The specific reference sign acquisition unit 42 acquires a FOUP number 83 which is a specific reference sign of the predetermined container 82 as one of the containers 80 that are being transported within the factory 90 or are in a state ready to be transported (information transmission (1)). As shown in FIG. 2, the processing device control unit 14 controls a readout unit of the corresponding load port apparatus 50, and the FOUP number 83 as the specific reference sign which identifies the predetermined container 82 mounted to the load port apparatus 50 by scanning an identification tag or an identification code given to the predetermined container 82. As such, the processing unit control unit 14 and the load port apparatus 50 work together and configures the specific reference sign acquisition unit 42.

Note that, the specific reference sign acquisition unit 42 is not limited to those configured by the processing device control unit 14, the load port apparatus 50, etc.; and for example, the host computer 12 and the container transportation system 16 may work together and configure the specific reference sign acquisition unit 42. Also, the specific reference sign may be any reference signs as long as the arbitrary one among the containers 80 that are being transported in the factory 90 or are in a state ready to be transported can be identified. Hence, it may be numbers other than the FOUP number 83, such as symbols, other reference signs, or reference sings combining numbers and symbols.

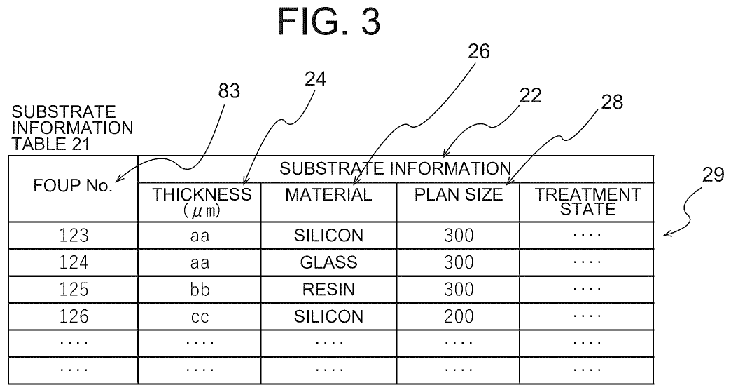

The substrate information storage unit 44 in the substrate information acquisition unit 20 correlates and stores the FOUP number 83 of each container 80 and the substrate information 22 of the predetermined container 82 according to the FOUP number 83. In the example shown in FIG. 2, the storage unit included in the host computer 12 configures the substrate information storage unit 44. FIG. 3 is enlarged diagram of the substrate information 22 shown in FIG. 2, and it shows one example of the substrate information 22 that the host computer 12 as the substrate information storage unit 44 stores.

As a substrate information table 21 shown in FIG. 3 conceptually shows, the substrate information storage unit 44 correlates and stores the FOUP number 83 of each container 80 and the substrate information 22 which is the information of the substrate accommodated in the predetermined container 82 according to the FOUP reference sign 83. As shown in FIG. 3, examples of information included in the substrate information 22 include information 24 regarding the thickness of the substrate accommodated in the predetermined container, information 26 regarding the material of the substrate accommodated in the predetermined container, information 28 regarding a plan size of the substrate accommodated in the predetermined container 82, information regarding a plan shape of the substrate accommodated in the predetermined container 82, and information regarding a treatment state of the substrate.

The information readout unit 48 in the substrate information acquisition unit 20 shown in FIG. 2 uses the FOUP number 83 acquired by the specific reference sign acquisition unit 42, and reads the information 22 of the predetermined container 82 corresponding to the FOUP reference sign 83 which is a specific reference sign from the substrate information storage unit 44. In the example shown in FIG. 2, the processing device control unit 14 reads the information from the storage unit of the host computer 12; thereby, the substrate information 22 stored in the substrate information storage unit 44 can be read (information transmission (2) and information transmission (3) shown in FIG. 2). Therefore, in the substrate information acquisition unit 20 shown in FIG. 2, the processing device control unit 14 and the host computer 12 work together to configure the information readout unit 48.

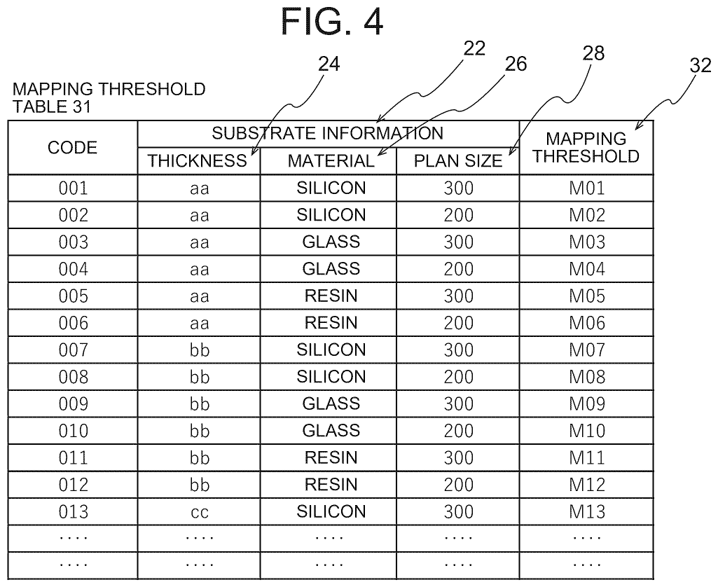

The processing device control unit 14 shown in FIG. 2 configures the mapping threshold determining unit 30, and by using the substrate information 22 that the substrate information acquisition unit 20 has acquired, the mapping threshold 32 used for mapping the predetermined container 82 is determined (see FIG. 4). The mapping threshold 32 that the processing device control unit 14 has determined is transferred to the mapping unit 60 where mapping for the predetermined container 82 is actually carried out (information transmission (4) shown in FIG. 2).

FIG. 4 shows one example of the mapping threshold table 31 which conceptually shows the process that the processing device control unit 14 as the mapping threshold determining unit 30 determines the mapping threshold 32 using the substrate information 22. As shown in FIG. 4, the mapping threshold determining unit 30 includes a mapping threshold table 31 which correlates a combination of information configuring the substrate information 22 such as the information 24 regarding the thickness of the substrate, the information 26 regarding the material of the substrate, and an information 28 regarding a plan size of the substrate with the value of the mapping threshold 32 which is appropriate at the moment.

The mapping threshold determining unit 30 applies the substrate information 22 which is acquired by the substrate information acquisition unit 20 to the mapping threshold 31 shown in FIG. 4; and thereby, the mapping threshold 32 used for mapping the predetermined container 82 can be determined. Here, the mapping threshold 32 refers to a threshold used to determine the accommodated state of the substrate based on the output result of the detection unit 64 used when the mapping unit 60 carries out mapping. Examples of the mapping threshold 32 refers to a range of a blocked distance (a combination of a lower limit and an upper limit) that the signal of the detection unit 64 of the mapping unit 60 is blocked by the substrate which is properly accommodated in the predetermined shelves in the container 80.

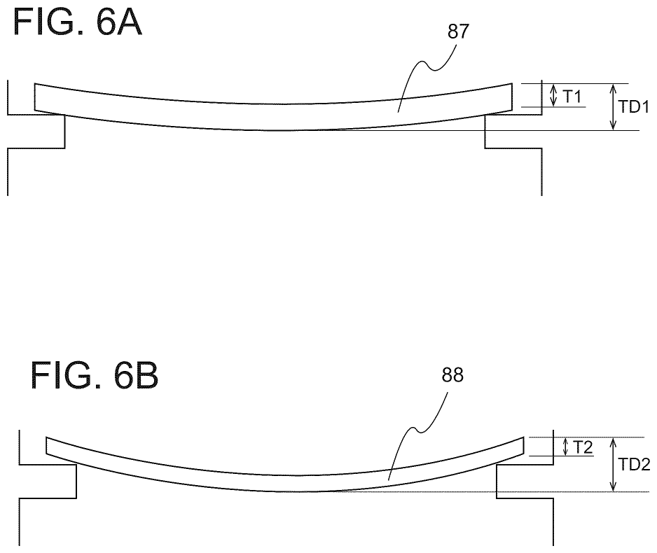

FIG. 6A schematically shows the state that a substrate 87 having a thickness T1 accommodated in the shelf of the container 80. When the mapping unit 60 carries out mapping to the substrate 87 shown in FIG. 6A, the signal of the detection unit 64 is blocked by the substrate 87 by the length which corresponds to the blocked distance TD1, and this is output to the detection unit 64. For example, as long as the blocked distance TD1 which is the output result of the detection unit 64 is between the lower limit and the upper limit, then the mapping unit 60 determines that the substrate 87 is properly accommodated. On the other hand, for example, when the blocked distance TD1 which is an output result of the detection unit 64 is smaller than the lower limit of the mapping threshold 32; then, the mapping unit 60 can determine that the substrate is not accommodated in the corresponding shelf. Also, for example, when the blocked distance TD1 which is an output result of the detection unit 64 is larger than the upper limit of the mapping threshold 32; then, the mapping unit 60 can determine that the substrate is improperly accommodated in the corresponding shelf such as two substrates being stacked.

As shown in FIG. 2, in the mapping system 10, the mapping unit 60 is incorporated as part of the load port apparatus 50 which docks the container 80 to the predetermined processing device 13. The mapping unit 60 carries out mapping for the predetermined container 82 which is mounted on the load port apparatus 50 using the mapping threshold 32 determined by the processing device control unit 14 as the mapping threshold determining unit 30.

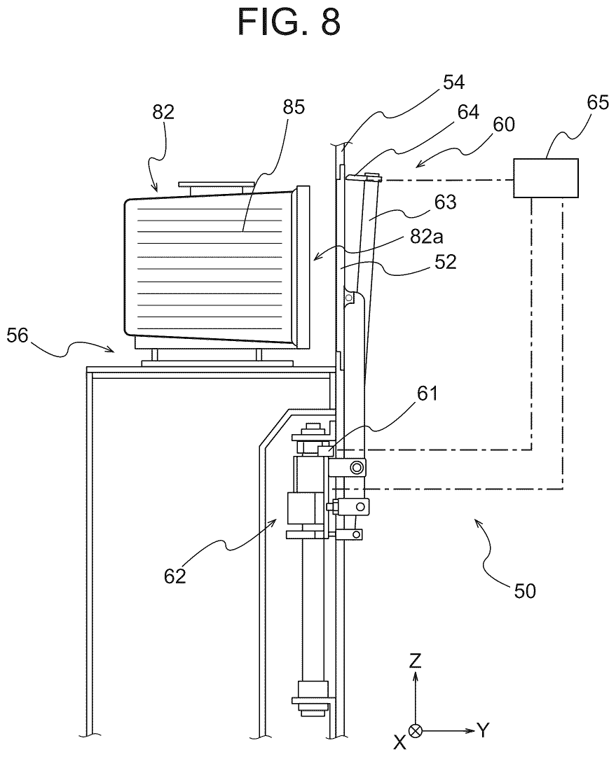

FIG. 8 is a conceptual diagram showing the first step of the mapping operation by the mapping unit 60 which is included in the load port apparatus 50 shown in FIG. 2; and, FIG. 8 is a partial cross-section diagram of the load port apparatus 50 viewing from the side (X-axis negative direction side). As shown in FIG. 8, the mapping unit 60 is provided near a door 52 of the load port apparatus 50.

As shown in FIG. 1, the load port apparatus 50 is used by installing to the processing device 13 via EFEM (not shown in the figure) in the semiconductor factory 90. The load port device 50 functions as an interface unit for passing the substrate such as a silicon wafer accommodated in the container 80 and transported in the semiconductor factory 90 to a treatment space inside the processing device 13 from the container 80. Note that, examples of the containers 80, which are being transported or are in a condition ready to be transported in the factory 90, include FOUP, FOSB, SMIF, and open cassette. Also, for the containers 80 in the factory 90, there may be containers accommodating substrates with different sizes such as FOUP accommodating a silicon wafer of 300 mm (12 inch) and a container accommodating silicon wafer of 200 mm (8 inch).

As shown in FIG. 8, the predetermined container 82 can accommodate the substrates 85 in a predetermined interval along the Z-axis negative direction which is a first direction. Also, the predetermined container 82 has a main opening at the lateral side of the container 82 (the Y-axis positive direction side) for taking out the substrate 85.

As shown in FIG. 8, in addition to the mapping unit 60, the load port apparatus 50 includes, a mounting part 56 for mounting the predetermined container 82, the frame 54 installed so as to cover the opening of EFEM, the door 52 which opens and closes the frame opening of the lid 82a of the frame 54 and the predetermined container 82, and so on.

The mapping unit 60 shown in FIG. 7 includes a mapping frame 63, the detection unit 64 installed to the mapping frame 63, a moving means 62 for moving the detection unit 64, a sensor position detection unit 61 detecting the position of the detection unit 64, the mapping control unit 65 controlling the mapping operation, and the like. FIG. 7 is an enlarged diagram of the detection unit 64 installed near the upper end of the mapping frame 63 shown in FIG. 8. As shown in FIG. 8, the detection unit 64 of the mapping unit 60 includes a light emitting part 64a, and a light reception part 64b which receives the light from the light emitting part 64a. By detecting the timing and the length of time that a detection axis 64c formed between the light emitting part 64a and the light reception part 64b is blocked by the substrate 85 accommodated in the predetermined container 82, the mapping unit 60 carries out mapping for the predetermined container 82.

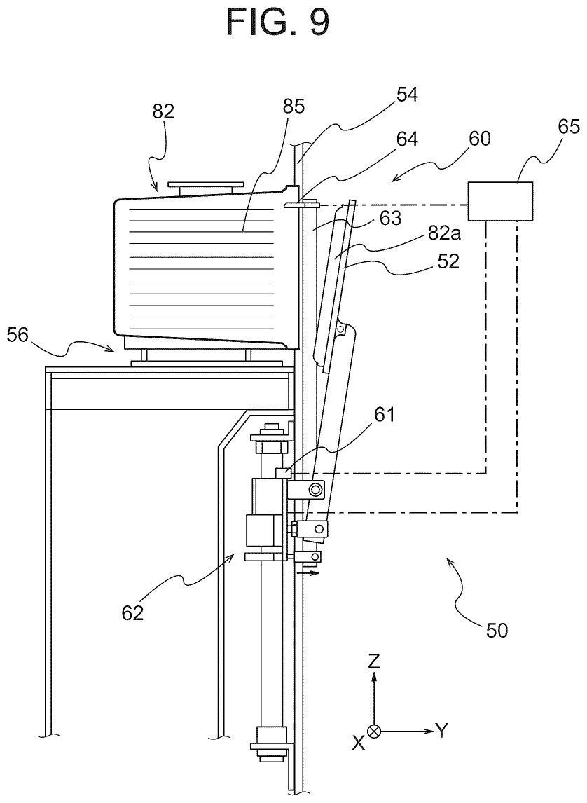

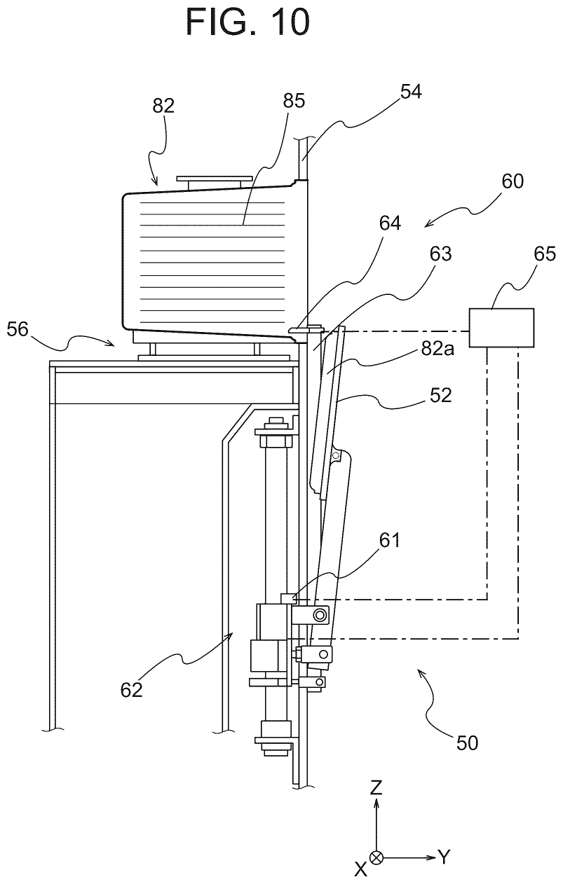

Below describes one example of the mapping operation performed by the mapping unit 60 by referring to FIG. 8 to FIG. 10. As shown in FIG. 8, in the first step of the mapping operation, the opening of the frame part 54 is closed by the door 15, and the mapping frame 63 is arranged by taking a predetermined distance from the opening of the frame 54 in the Y-axis positive direction. On the other hand, as shown in FIG. 9 and FIG. 10, when mapping is performed in the predetermined container 82, the mapping frame 63 moves from the state shown in FIG. 8 to the second direction (the Y-axis negative direction) which is roughly perpendicular to the first direction. Then, it further moves to the first direction (the Z-axis negative direction).

In the first step shown in FIG. 8, the predetermined container 82 accommodating a plurality of substrates 85 is mounted on the mounting part 56 of the load port apparatus 50, and the lid 82a of the predetermined container 82 is closed. Thus, the predetermined container 82 is not connected to the frame 54 of the load port apparatus 50. Also, in the state shown in FIG. 8, the mapping unit 60 itself has not started the mapping operation.

FIG. 9 shows the second step of the mapping operation of the mapping unit 60. In the second step shown in FIG. 9, the predetermined container 82 mounted on the mounting part 56 is connected to the frame 54, and the door 52 opens the lid 82a of the predetermined container 82. The door 52 engages with the lid 82a of the predetermined container 82 while being engaged to the frame 54, then a door driving means shown in FIG. 8 pulls the door 52 to the Y-axis positive direction, and the lid 82a of the predetermined container 82 is opened.

Further, the moving means 62 of the mapping unit 60 moves the upper end part of the mapping frame 63 to the second direction (the Y-axis negative direction), and at least part of the detection unit 64 fixed to the mapping frame 63 is inserted inside the predetermined container 82. Thereby, the detection axis 64c of the detection unit 64 is arranged above the substrate 85 accommodated in the predetermined container 82.

FIG. 10 shows the third step of the mapping operation by the mapping unit 60. In the third step shown in FIG. 10, as the moving means 62 moves the mapping frame 63 to the first direction (the Z-axis negative direction), the detection unit 64, which is arranged at the position higher than the substrate 85 accommodated in the top shelf as shown in FIG. 9, is moved to the position lower than the substrate 85 accommodated in the lowest shelf as shown in FIG. 10.

That is, the moving means 62 moves the detection axis 64c of the detection unit 64 along the first direction, which is the arrangement direction, so that the detection axis 64c sequentially intersects the substrates 85 accommodated in the predetermined container 82 one by one. Here, the detection unit 64 output detection signals, which change in response to blocking of the detection axis 64c by the substrate 85, to the mapping control unit 65 shown in FIG. 8 to FIG. 10. Also, the mapping unit 60 includes the sensor position detection unit 61; and, the sensor position detection unit 61 detects the position of the detection unit 64 in the Z-axis direction, and then outputs the position to the mapping control unit 65.

For example, the blocked distances TD1 and TD2 (see FIG. 6A to FIG. 6B) are calculated using the output signal from the detection unit 64 and the position information from the sensor position detection unit 61; then, the blocked distances TD1 and TD2 are compared to the mapping threshold 32 determined by the mapping threshold determining unit 30 shown in FIG. 2 (see FIG. 4). Thereby, the mapping control unit 65 detects the accommodated state of the substrate 85 accommodated in the predetermined container 82 (information transmission (5) shown in FIG. 2). Note that, the mapping control unit 65 of the mapping unit 60 shown in FIG. 8 to FIG. 10 is, for example, configured of a micro controller, memory, etc. Also, the mapping control unit 65 may be formed integral with a load port control unit which controls the entire load port apparatus 50.

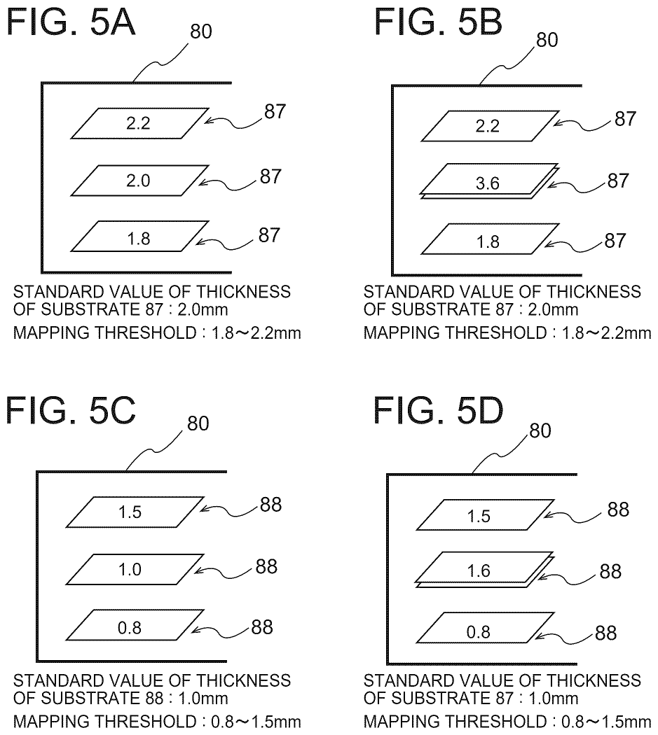

FIG. 5A to FIG. 5D are conceptual diagrams explaining the relationship between the blocked distances TD1 and TD2 detected by the detection unit 64, etc., of the mapping unit 60 and the appropriate mapping threshold 32. FIG. 5A and FIG. 5B are conceptual diagram showing one example of the blocked distance TD1 which the mapping unit 60 detects from each substrate 87 accommodated in the container 80 when the substrate 87 has a thickness T1 of 2 mm as shown in FIG. 6A. When the thickness T1 of the substrate is relatively thick as shown in FIG. 6A, the warpage of the substrate accommodated in the container 80 is relatively small. Therefore, when the thickness T1 of the substrate 87 is 2 mm, it is possible to detect properly accommodated state of the substrate by setting the mapping threshold 32 to plus and minus 0.2 mm from the standard value of the thickness of the substrate 87 as shown in FIG. 5A and FIG. 5B. Note that, in the second row of FIG. 5B, two substrates 87 are stacked and accommodated; hence, the detected blocked distance TD1 is larger than the upper limit of the mapping threshold 32. Hence, it is shown that the mapping unit 60 accurately detects the improperly accommodated state.

On the other hand, FIG. 5C and FIG. 5D show the conceptual diagrams of one example of the blocked distance TD2 which the mapping unit 60 detects from each substrate 88 accommodated in the container 80 when the substrate 88 has a thickness T2 of 1 mm as shown in FIG. 6B. When the thickness T2 of the substrate is relatively thin as shown in FIG. 6B, the warpage of the substrate accommodated in the container 80 is relatively large. Thus, when the thickness T2 of the substrate 88 is 1 mm, if the mapping threshold 32 is set to plus and minus 0.2 mm from the thickness of the substrate 88 as similar to the case of the substrate 87 which the thickness T1 is 2 mm, the detected blocked distance TD2 becomes larger than the mapping threshold 32 even though the substrate 88 is properly accommodated as shown in the first row of the substrate 88 shown in FIG. 5C. Thus, the mapping unit 60 mistakenly determines that the substrate 88 in the first row of FIG. 5C is improperly accommodated.

Therefore, in the mapping unit 60 shown in FIG. 2 and the like, the mapping threshold 32 is not set uniformly, and the mapping threshold 32 is set per each container 80 using the substrate information 22 which is the information of the substrate 85 accommodated in the predetermined container 82. For example, as shown in FIG. 5C and FIG. 5D, when the thickness T2 of the substrate 88 is set to 1 mm, the mapping threshold is set to a range of 0.8 to 1.5 mm which is minus 0.2 mm to plus 0.5 mm from the standard value of the thickness of the substrate 88; thereby, the properly accommodated state of the substrate can be detected. Note that, in the second row of FIG. 5D, two substrates 88 are stacked and accommodated; hence, the detected blocked distance TD2 is larger than the mapping threshold 32. Thus, the mapping unit 60 accurately detects the improperly accommodated state. As such, the mapping threshold determining unit 30 can be set to any mapping threshold 32, and for example, the range between the standard value of the thickness of the substrate 88 and the upper limit of the mapping threshold 32 can be wider than the range between the standard value of the thickness of the substrate 88 and the lower limit of the mapping threshold 32.

As such, according to the mapping system 10 shown in FIG. 2, etc., the substrate information 22 is acquired which is the information of the substrate accommodated in a container 80 which is being transported in the factory 90; and then, based on the substrate information 22, the mapping threshold for mapping the predetermined container 82 can be determined. Thereby, the mapping unit 60 can carry out mapping using the mapping threshold which is optimized to each of the substrates 85, 87, and 88 accommodated in the predetermined container 82. Therefore, the mapping system 10 can accurately detect the accommodated state of the object accommodated in the container 80 even in the case that the containers accommodating objects with different materials and shapes are transported in the factory 90.

Also, as similar to the case of the thickness of the substrate described using FIG. 5A to FIG. 5D, also the material of the substrate and the plan size of the substrate may cause difference in the warpage of the substrate when it is accommodated, and in optical properties such as a light scattering property of the light emitting part 64a included in the detection part 64. Therefore, by determining the mapping threshold using the substrate information 22 as shown in FIG. 3 and FIG. 4, the mapping system 10 accurately detects the accommodated state of the object accommodated in the container 80.

Also, the substrate information acquisition unit 20 of the mapping system 10 shown in FIG. 2 can acquire the substrate information 22 regarding the substrate accommodated in the predetermined container 82 just by acquiring the specific reference sign of the predetermined container 82 from the container; thus, the container 80 only needs to hold simple information. Hence, the system can be simplified.

As discussed in above, the mapping system 10 according to the present disclosure is described using the specific embodiment. The technical scope of the mapping system according to the present disclosure is not limited to the above-mentioned embodiment; and, it can of course include other embodiments and examples. For example, in the mapping system 10 according to the first embodiment shown in FIG. 2, the storage unit of the host computer 12 stores the substrate information 22, however, unlike this, the storage unit of the processing device control unit 14 may store the substrate information 22.

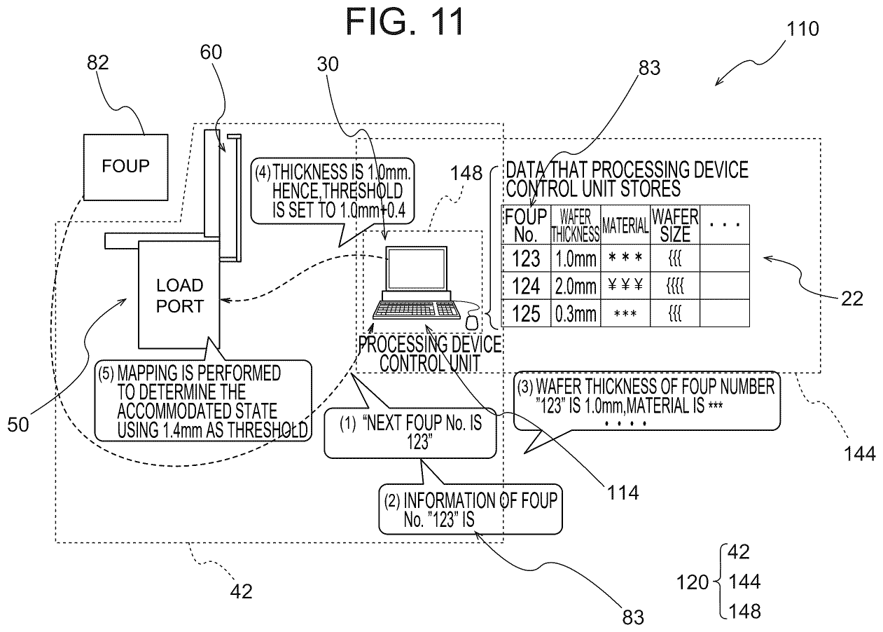

FIG. 11 is a conceptual diagram showing the information transmission performed in each part included in the mapping system 110 according to the second embodiment. The mapping system 110 is basically the same as the mapping system 10 shown in FIG. 2 except that a storage unit of a processing device control unit 114 stores the substrate information 22. Regarding the mapping system 110, the points which are different from the mapping system 10 are mainly explained, and the parts which are common with the mapping system 10 are given with the same numerical references and the explanation will be omitted.

In the mapping system 110 shown in FIG. 11, the processing device control unit 114 and the load port apparatus 50 work together and configures the substrate information acquisition unit 120. That is, in the specific reference sign acquisition unit 42 of the substrate information acquisition unit 120, the FOUP number 83 for the predetermined container 82 mounted on the load port apparatus 50 is passed from the load port apparatus 50; thereby, the processing device control unit 114 acquires the FOUP number 83 as the specific reference sign from the corresponding load port apparatus 50 (information transmission (1) of FIG. 11).

On the other hand, the processing device control unit 114 shown in FIG. 11 includes a storage unit which correlates and stores the FOUP number 83 of each container 80 in the semiconductor factory 90 and the substrate information 22 which is the information of the substrate accommodated in the predetermined container corresponding to the FOUP number 83 (see FIG. 3). Therefore, in the example shown in FIG. 11, the storage unit included in the processing device control unit 114 configures the substrate information storage unit 144.

Also, in the mapping system 110 shown in FIG. 11, the processing device control unit 114 reads the substrate information 22 from the storage unit included in the processing device control unit 114; thereby, the substrate information 22 is read (information transmission (2) and information transmission (3) shown in FIG. 11). Therefore, in the substrate information acquisition unit 120 shown in FIG. 11, the processing device control unit 114 alone configures the information readout unit 148.

Regarding the mapping threshold determining unit 30 and the mapping unit 60 of the mapping system 110, these are similar to the mapping threshold determining unit 30 and the mapping unit 60 of the mapping system 10 shown in FIG. 2. In the mapping system 110 shown in FIG. 11, each processing device control unit 114 includes the substrate information 22; thus, it is possible to reduce communication load particularly of the host computer 12 in the semiconductor factory 90. Furthermore, the parts of the mapping system 110 shown in FIG. 11 in which are common with the mapping system 10 exhibit the similar effects as in the case of the mapping system 10. Note that, as shown FIG. 2, the mapping system 10 which the host computer 12 centrally controls the substrate information 22, changes and updates of the substrate information 22 can be carried out rapidly and easily.

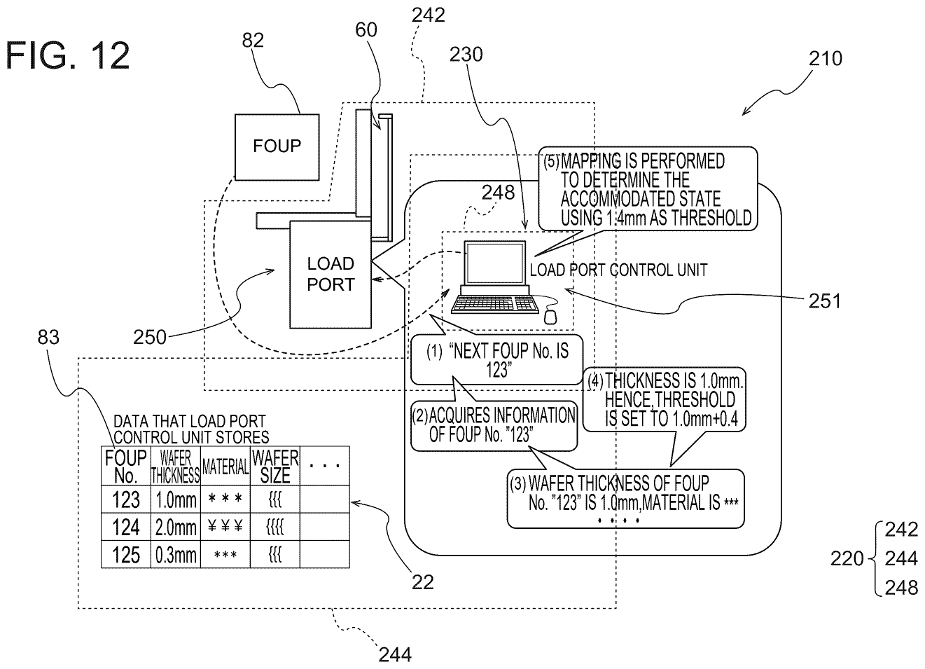

FIG. 12 is a conceptual diagram showing the information transmission carried out in each part included in a mapping system 210 according to the third embodiment. The mapping system 210 is basically the same as the mapping system 10 except that, in the mapping system 210, a storage unit of a load port apparatus control unit 251 as a control unit of a load port apparatus 250 stores the substrate information 22. Regarding the mapping system 210, the points which are different from the mapping system 10 are mainly explained, and the parts which are common with the mapping system 10 are given with the same numerical references and the explanation will be omitted.

In the mapping system 210 shown in FIG. 12, the load port apparatus 50 alone configures a substrate information acquisition unit 220. That is, in a specific reference sign acquisition unit 242 of the substrate information acquisition unit 220, a load port apparatus control unit 251 controls a scanning device and so on of the load port apparatus 250; thereby, the FOUP number 83 of the predetermined container 82 mounted on the load port apparatus 250 is read to acquire the FOUP number 83 as the specific reference sign (information transmission (1) of FIG. 12).

Also, the load port control unit 251 shown in FIG. 12 includes a storage unit which correlates and stores the FOUP number 83 of each container 80 in the semiconductor factory 90, and the substrate information 22 which is the information of the substrate accommodated in the predetermined container 82 corresponding to the FOUP number 83 (see FIG. 3). Therefore, in the example shown in FIG. 12, the storage unit included in the load port apparatus control unit 251 configures the substrate information storage unit 244.

Also, in the mapping system 210 shown in FIG. 12, the load port apparatus control unit 251 reads the substrate information 22 from the storage unit which is included the load port apparatus control unit 251 itself; thereby, the substrate information 22 is read (information transmission (2) and information transmission (3) in FIG. 12). Therefore, in the substrate information acquisition unit 220 shown in FIG. 12, the load port apparatus control unit 251 alone configures the information readout unit 248.

Also, the mapping threshold determining unit 230 of the mapping system 210 is configured of the load port apparatus control unit 251. That is, the load port apparatus control unit 251 determines the mapping threshold 32 (see FIG. 4) used for mapping the predetermined container 82 using the substrate information 22 which is read from the storage unit that the load port apparatus control unit 251 itself has. Regarding the mapping unit 60, it is similar to the mapping unit 60 of the mapping system 10 shown in FIG. 2.

In the mapping system 210 shown in FIG. 12, by performing information transmission or information processing in the load port apparatus 50, it is possible to determine the mapping threshold based on the substrate information 22 of each container 80 and mapping using this. Therefore, the mapping system 210 can be achieved without making any changes to the host computer 12 or the processing device control unit 14 (see FIG. 2) in the semiconductor factory 90. Also, the mapping system 210 enables to reduce communication load of the semiconductor factory 90.

Note that, each configuration included in the above-mentioned mapping systems 10, 110, and 210 are merely examples of the mapping system according to the present disclosure, and it can be replaced with other configurations which enables to achieve the object of the present disclosure. For example, the mapping unit 60 shown in FIG. 7 is not limited to the optical detection unit, and other than using lights, a detection unit using electromagnetic waves can be used.

### DESCRIPTION OF THE REFERENCE NUMERICAL

10, 110, 210 . . . Mapping system
12 . . . Host computer
13 . . . Processing device
14, 114 . . . Processing device control unit
16 . . . Container transportation system
20, 120, 220 . . . Substrate information acquisition unit
21 . . . Substrate information table
22 . . . Substrate information
24 . . . Thickness of substrate
26 . . . Material of substrate
28 . . . Plan size
30, 230 . . . Mapping threshold determining unit
31 . . . Mapping threshold table
32 . . . Mapping threshold
42, 242 . . . Specific reference sign acquisition unit
44, 144, 244 . . . Substrate information storage unit
48, 148, 248 . . . Information readout unit
50, 250 . . . Load port apparatus
251 . . . Load port apparatus control unit
52 . . . Door
54 . . . Frame
56 . . . Mounting part
60 . . . Mapping unit
61 . . . Sensor position detection unit
62 . . . Moving means
63 . . . Mapping frame
64 . . . Detection unit
64a . . . Light emitting part
64b . . . Light reception part
64c . . . Detection axis
65 . . . Mapping control unit
80 . . . Container
82 . . . Predetermined container
82a . . . Lid
83 . . . FOUP number (specific reference sign)
85, 87, 88 . . . Substrate
90 . . . Factory

1. A mapping system comprising:
a substrate information acquisition unit acquiring a substrate information regarding a substrate accommodated in a predetermined container that is being transported or is in a state ready to be transported within a factory;
a mapping threshold determining unit determining a mapping threshold used for mapping the predetermined container based on the substrate information; and
a mapping unit for mapping the predetermined container using the mapping threshold.

2. The mapping system according to claim 1, wherein the substrate information includes an information regarding a thickness of the substrate accommodated in the predetermined container.

3. The mapping system according to claim 1, wherein the substrate information includes an information regarding a material of the substrate accommodated in the predetermined container.

4. The mapping system according to claim 1, wherein
the substrate information acquisition unit comprises:
a specific reference sign acquisition unit acquiring a specific reference sign of the predetermined container that is being transported or is in a state ready to be transported within a factory,
a substrate information storage unit correlating and storing the specific reference sign and the substrate information of the predetermined container according to the reference sign, and
an information readout unit reading the substrate information of the predetermined container corresponding to the specific reference sign from the substrate information storage unit using the specific reference sign acquired by the specific reference sign acquisition unit.
